(19) United States
(12) Patent Application Publication
(10) Pub. No.: US 2018/0198436 A1
(43) Pub. Date: Jul. 12, 2018

(54) RADIO-FREQUENCY PACKAGE WITH OVERMOLD STRUCTURE

(71) Applicant: SKYWORKS SOLUTIONS, INC., Woburn, MA (US)

(72) Inventor: Jaydutt Jagdish JOSHI, Irvine, CA (US)

(21) Appl. No.: 15/835,447

(22) Filed: Dec. 7, 2017

Related U.S. Application Data
(60) Provisional application No. 62/431,378, filed on Dec. 7, 2016.

(51) Int. Cl. H03H 9/10; H03H 9/17; H03H 3/02; H03H 9/54; H05K 1/18; H03H 9/70; H04B 1/40

(52) U.S. Cl. CPC H03H 9/1042; H03H 9/17; H03H 3/02; H05K 2201/1006; H05K 1/181; H03H 9/706; H04B 1/40; H03H 9/54

(57) ABSTRACT

According to some implementations, a radio-frequency (RF) module is disclosed, comprising a first substrate. The radio-frequency module also includes a radio-frequency device mounted on the first substrate, the radio-frequency device including a second substrate. In some embodiments, the second substrate includes a first side and a second side, a set of support structures implemented on the second side of the substrate, the set of support structures defining a mounting volume on the second side of the second substrate, and a component implemented within the mounting volume. The radio-frequency module may further comprise a first overmold structure encapsulating at least a portion of the set of support structures.

### CROSS-REFERENCE TO RELATED APPLICATION

This application claims priority to U.S. Provisional Application No. 62/431,378 filed Dec. 7, 2016, entitled RADIO-FREQUENCY PACKAGE WITH OVERMOLD STRUCTURE. The contents of each of the above-referenced application(s) are hereby expressly incorporated by reference herein in their entireties for all purposes.

### BACKGROUND

### Field

The present disclosure relates to semiconductor packaging technology.

### Description of the Related Art

Packaging of electronic circuitry is of critical concern for the longevity and performance of such electronic circuitry. Packaging techniques can protect sensitive electronic components from environmental conditions, contaminants and undesirable electro-magnetic interference, among other nuisances. The present disclosure relates to packaging of electronic modules (such as radio-frequency (RF) modules) and/or electronic devices (such as RF devices). In radio-frequency (RF) applications, RF circuits and related devices can be implemented in a module (e.g., an RF module). Such a module can then be mounted on a circuit board such as a phone board.

### SUMMARY

In some implementations, the present disclosure relates to a radio-frequency module comprising a first substrate. The radio-frequency (RF) module may include a radio-frequency device mounted on the first substrate. The RF device may include a second substrate, the second substrate including a first side and a second side, a set of support structures implemented on the second side of the substrate, the set of support structures defining a mounting volume on the second side of the second substrate, and a component implemented within the mounting volume. In some embodiments, the radio-frequency module may further include a first overmold structure encapsulating at least a portion of the set of support structures.

In some embodiments, the radio-frequency device comprises a radio-frequency filter. In some embodiments, the radio-frequency filter comprises a bulk acoustic wave filter.

In some embodiments, the component comprises a resonator. In some embodiments, the component is not encapsulated by the first overmold structure. In some embodiments, the mounting volume is substantially devoid of the first overmold structure. In some embodiments, the set of support structures is configured to prevent the first overmold structure from filling the mounting volume during a manufacturing process.

In some embodiments, a layout of the set of support structures prevents the first overmold structure from filling the mounting volume during a manufacturing process. In some embodiments, the layout of the set of support structures is based on a temperature of the first overmold structure during the manufacturing process. In some embodiments, the layout of the set of support structures is based on an amount of overmold material in the first overmold structure during the manufacturing process. In some embodiments, the layout of the set of support structures is based on a viscosity of the first overmold structure during the manufacturing process.

In some embodiments, at least a portion of the set of support structures is exposed through the first overmold structure. In some embodiments, the set of support structures comprises a metallic material.

In some embodiments, the set of support structures is configured to allow the radio-frequency device to be mounted on the first substrate. In some embodiments, the set of support structures comprises a first group of support structures arranged to partially or fully surround the component mounted on the second side of the second substrate. In some embodiments, the set of support structures further comprises a second group of support structures arranged to partially or fully surround the first group of support structures.

In some embodiments, at least one support structure of the set of support structures is electrically connected to a circuit located on the second substrate. In some embodiments, the circuit is located on the first side of the second substrate.

In some embodiments, at least one support structure of the set of support structures is electrically connected to a ground plane within the first substrate. In some embodiments, the set of support structures comprises a ball grid array (BGA). In some embodiments, the BGA comprises a set of solder balls.

In some embodiments, the set of support structures comprises a plurality of pillars. In some embodiments, the set of support structures forms a rectangular perimeter around the component mounted on the second side of the second substrate.

In some embodiments, the component includes an SMT device. In some embodiments, the SMT device includes a passive device or an active radio-frequency device. In some embodiments, the component includes a die. In some embodiments, the die includes a semiconductor die. In some embodiments, the semiconductor die is configured to facilitate processing of radio-frequency signals using a circuit located on the first side of the second substrate.

In some embodiments, the set of support structures is configured to prevent the component from contacting a circuit board when the radio-frequency device is mounted on the circuit board. In some embodiments, the set of support structures is configured to create an air cavity when the radio-frequency device is mounted on a circuit board.

In some implementations, the present disclosure comprises providing a first substrate configured to receive a plurality of components, the first substrate including a first side and a second side and forming a set of support structures on the second side of the first substrate such that the set of support structures is positioned relative to the component, the set of support structures defining a mounting volume on the second side of the first substrate. The method may also include mounting a component within the mounting volume on the second side of the first substrate, mounting the first substrate and the set of support structures on a second substrate and forming a first overmold structure between the first substrate and the second substrate, the mounting volume being substantially devoid of the first overmold structure.

In some implementations, the method further includes mounting a circuit on the first side of the first substrate.

In some implementations, the method further includes electrically connecting at least one support structure in the set of support structures to the circuit on the first side of the first substrate. In some implementations, the method further includes electrically connecting at least one support structure in the set of support structures to a ground plane in the second substrate.

In some implementations, the method further includes removing a portion of the first overmold structure.

In some implementations, the present disclosure relates to a radio-frequency (RF) device comprising a substrate, the substrate including a first side and a second side. In some embodiments, the RF device includes a set of support structures implemented on the second side of the substrate, the set of support structures defining a mounting volume on the second side of the substrate and a component implemented within the mounting volume.

In some implementations, the present disclosure relates to a wireless device comprising a circuit board configured to receive a plurality of packaged modules. The wireless device may include a radio-frequency module mounted on the circuit board, the radio-frequency device including a first substrate, an RF device mounted on the first substrate, the RF device including a second substrate, the second substrate including a first side and a second side, a set of support structures implemented on the second side of the substrate, the set of support structures defining a mounting volume on the second side of the second substrate, and a component implemented within the mounting volume. In some embodiments, the radio-frequency module of the wireless device includes a first overmold structure encapsulating at least a portion of the set of support structures.

### BRIEF DESCRIPTION OF THE DRAWINGS

FIG. 1A illustrates a perspective view of an underside of an example RF device, according to some embodiments of the present disclosure.

FIG. 1B illustrates a top-down view of an underside of the example RF device illustrated in FIG. 1A, according to some embodiments of the present disclosure.

FIG. 2A illustrates a stage of a fabrication process in which RF devices may be implemented in a panel format, according to some embodiments of the present disclosure.

FIG. 2B illustrates a stage of a fabrication process in which RF devices may be implemented in a panel format, according to some embodiments of the present disclosure.

FIG. 2C illustrates a stage of a fabrication process in which RF devices may be implemented in a panel format, according to some embodiments of the present disclosure.

FIG. 2D illustrates a stage of a fabrication process in which RF devices may be implemented in a panel format, according to some embodiments of the present disclosure.

FIG. 2E illustrates a stage of a fabrication process in which RF devices may be implemented in a panel format, according to some embodiments of the present disclosure.

FIG. 2F illustrates a stage of a fabrication process in which RF devices may be implemented in a panel format, according to some embodiments of the present disclosure.

FIG. 3 illustrates a top-down view of the underside of an example RF device during a manufacture/fabrication process, according to some embodiments of the present disclosure.

FIG. 4 illustrates a top-down view of the underside of an example RF device during a manufacture/fabrication process, according to some embodiments of the present disclosure.

FIG. 5 illustrates as top-down perspective view of an RF module, according to some embodiments of the present disclosure.

FIG. 6 illustrates as top-down perspective view of an RF module, according to some embodiments of the present disclosure.

FIG. 7 illustrates a top-down view of the underside of an example RF device, according to some embodiments of the present disclosure.

FIG. 8 illustrates a radio-frequency device having one or more features as described herein, implemented as a radio-frequency module.

FIG. 9 illustrates a radio-frequency device and/or radio-frequency module implemented in a wireless device, according to some embodiments of the present disclosure.

### DETAILED DESCRIPTION OF SOME EMBODIMENTS

The headings provided herein, if any, are for convenience only and do not necessarily affect the scope or meaning of the claimed invention.

The present disclosure relates to electronic modules (such as radio-frequency (RF) modules) and/or electronic devices (such as RF devices). In radio-frequency (RF) applications, RF circuits and related devices can be implemented in a module (e.g., an RF module). Such a module can then be mounted on a circuit board such as a phone board.

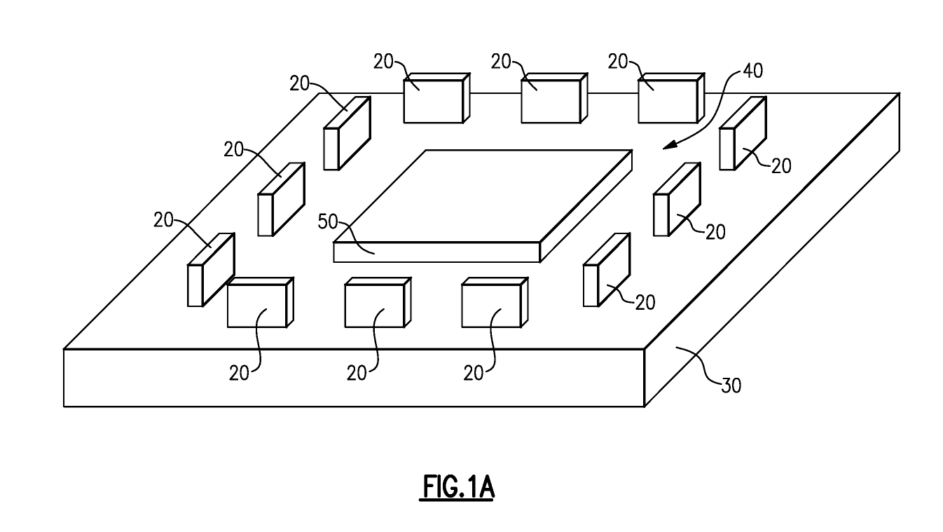

FIG. 1A illustrates a perspective view of a bottom (e.g., an underside) of an example RF device, according to some embodiments of the present disclosure. The RF device includes a substrate 30. The substrate has a first side (e.g., an upper side) and a second side (e.g., a lower side). In FIG. 1A, the RF device is inverted (e.g., is upside down) such that the second side (e.g., the lower side) is facing upward and the first side (e.g., the upper side) is facing downward. In one embodiment, the substrate 30 may be a semiconductor substrate. For example, the substrate 30 may be a silicon substrate, a wafer, a die (e.g., a semiconductor die), etc. In another embodiment, FIG. 1A may illustrate a perspective view of the bottom of the example RF device (illustrated in FIG. 1A) before the example RF device is placed (e.g., installed, mounted, etc.) on a packaging substrate (such as a laminate substrate).

The RF device also includes a set of support structures 20. As illustrated in FIG. 1A (and as discussed in more detail below), the support structures 20 may form and/or define a mounting volume 40 on the second side of the substrate 30. For example, the set of support structures may define a rectangular shaped volume (e.g., a space, a region, a cavity, etc.), as discussed in more detail below. One having ordinary skill in the art understands that examples of support structures may include (but are not limited to) pillars, columns, posts, pedestals, spheres, balls (e.g., a ball grid array (BGA), solder balls), etc. For example, the support structures may be copper pillars formed using a copper pillar bump/bumping process. In one embodiment, a support structure (or a set of support structures) may be any structure and/or component that may be used to support the RF device 10 above a surface. In another embodiment, a support structure may be any structure and/or component that may be used to define the mounting volume 40.

The RF device also includes a component 50. The component 50 is located within the mounting volume 40. For example, the component 50 may implemented, formed, installed, mounted, attached, etc., on the substrate 30 within the mounting volume 40. The mounting volume 40 may be substantially devoid of an overmold structure (discussed below). This may allow the component 50 to be mounted within the mounting volume 40. As illustrated in FIG. 1A, the component 50 may not be encapsulated by the overmold structure.

In one embodiment, the RF device may be a filter, such as an RF filter. For example, the RF device may be an RF filter that may allow signals (e.g., RF signals) of different frequencies to pass through the RF filter. In another example, the RF device may be an RF filter that may prevent signals (e.g., RF signals) of different frequencies from passing through the RF filter.

In one embodiment, the RF device may be a bulk acoustic wave filter (BAW). The component 50 may be a resonator of the BAW. For example, the component 50 may include a piezoelectric film that may function as a resonator for the BAW. As illustrated in FIG. 1A, the mounting volume 40 includes an air cavity (e.g., an unfilled gap, open space, etc.). In some embodiments, the air cavity (of the mounting volume 40) may be useful for the operation of the RF device. For example, the air cavity may allow the resonator to function properly to allow the BAW to perform filtering functions. In some embodiments, the air cavity allows for the RF device to perform filtering functions (e.g., at the module level) without the use or requirement of an interposer or wafer-level packaging. In some embodiments, the air cavity is a component of a package filter created by any of the structures described in this disclosure. For example, forming an air cavity (e.g., within mounting volume 40) creates isolation for one or more components on the RF device from overmold compound which may otherwise require additional components (e.g., interposers) to compensate for noise, or other undesirable effects of contact with the overmold.

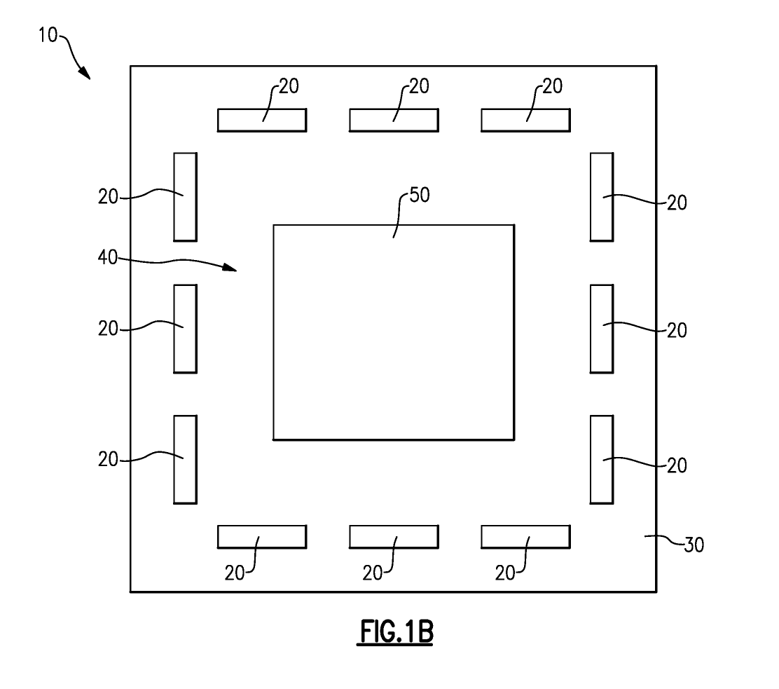

In some embodiments, the support structures 20 may be a metallic material (e.g., may be composed of or may consist of a metallic material). For example, the support structures 20 may be a copper material, a metallic alloy, etc. In other embodiments, the support structures may be configured to allow the RF device 10 to be mounted (e.g., installed, placed, etc.) on a circuit board and/or another module. In one embodiment, the set of support structures 20 may have a height (e.g., may be tall enough) that may prevent the component 50 from contacting a circuit board when the RF device is mounted on the circuit board. For example, the support structures 20 may be taller than the height of the component 50 (as illustrated in FIG. 2F). In another embodiment, the set of support structures may be configured to create an air cavity (e.g., an open space, a pocket of air, etc.) when the RF device is mounted on a circuit board.

In one embodiment, an additional circuit (or additional component, module, device, etc.), may be located on the substrate 30. For example, the additional circuit may be located on the first side of the substrate 30 (e.g., the upper side of the substrate 30 which is shown as facing downward in FIG. 1A). One or more support structures 20 may be electrically connected (e.g., electrically coupled) to the additional circuit. This may allow the additional circuit to transmit and/or receive signals via the one or more support structures (that are electrically connected to the additional circuit). This may also allow the additional circuit to transmit and/or receive signals to a circuit board. In another embodiment, at least one support structure 20 may be electrically connected to a ground plane within the substrate (not illustrated in the figures).

One having ordinary skill in the art understands that the component 50 may any device, module, circuit, etc., that can be placed, mounted, formed, and/or installed (within the mounting volume 40) on the substrate 30. In some embodiments, such a device, module, circuit, etc., may be an active RF device or a passive device that facilitates processing of RF signals. By way of non-limiting examples, such a device, module, circuit, etc., may include a die such as a semiconductor die, an integrated passive device (IPD), a surface-mount technology (SMT) device, and the like. In one embodiment, the component 50 may be a semiconductor die that may facilitate processing of RF signals by a circuit located on the first side of the substrate 30.

FIG. 1B illustrates an overhead (e.g., top-down) view of a bottom (e.g., an underside) of the example RF device 10 illustrated in FIG. 1A, according to some embodiments of the present disclosure. As discussed above, the RF device 10 includes the substrate 30, support structures 20, and the component 50. Also as discussed above, the RF device 10 is inverted such that the bottom of the RF device is visible. For example, the bottom of the substrate 30 is visible. As illustrated in FIG. 1B, the support structures 20 form and/or define the mounting volume 40. One having ordinary skill in the art understands that examples of support structures may include (but are not limited to) pillars, columns, posts, pedestals, spheres, balls (e.g., solder balls), etc. In one embodiment, a support structure (or a set of support structures) may be any structure and/or component that may be used to support the RF device 10 above a surface. In another embodiment, a support structure may be any structure and/or component that may be used to define the mounting volume 40. In some embodiments, the support structures 20 may be a metallic material (e.g., may be composed of or may consist of a metallic material). In one embodiment, the set of support structures 20 may have a height (e.g., may be tall enough) that may prevent the component 50 from contacting a circuit board when the RF device 10 is mounted on the circuit board. In another embodiment, the set of support structures may be configured to create an air cavity (e.g., an open space, a pocket of air, etc.) when the RF device is mounted on a circuit board.

The component 50 is located within the mounting volume 40. The support structures 20 (e.g., the layout, spacing, and/or number of support structures 20) may prevent overmold material (e.g., an overmold structure) from filling the mounting volume, as discussed in more detail below. This may allow the component 50 to be mounted within the mounting volume 40. One having ordinary skill in the art understands that the component 50 may any device, module, circuit, etc., (e.g., an IPD, a semiconductor die, an SMT, etc.) that can be placed, mounted, formed, and/or installed (within the mounting volume 40) on the substrate 30.

In one embodiment, the RF device 10 may be (or include) a filter, such as an RF filter. For example, the RF device may be a BAW and the component 50 may be a resonator (e.g., a piezoelectric film) of the BAW. As discussed above, the mounting volume 40 includes an air cavity (e.g., an unfilled gap, open space, etc.) and the air cavity (of the mounting volume 40) may be useful for the operation of the RF device 10.

In one embodiment, an additional circuit (or additional component, module, device, etc.), may be located on the substrate 30, as discussed above. For example, the additional circuit may be located on the upper side of the substrate 30 (which is not visible in FIG. 1B because the RF device 10 is inverted). One or more support structures 20 may be electrically connected (e.g., electrically coupled) to the additional circuit, as discussed above. In another embodiment, at least one support structure 20 may be electrically connected to a ground plane within the substrate (not illustrated in the figures), as discussed above.

### Examples Related to Fabrication

FIGS. 2A-2F illustrate various stages of a fabrication process in which substantially RF devices may be implemented in a panel format having an array of to-be-separated units, before such units are separated (also referred to as singulated). Although described in the context of pillars (e.g., column, posts, etc.), one having ordinary skill in the art understands that one or more features of the fabrication technique of FIGS. 2A-2F may also be implemented for fabrication of RF devices having other types of support structures. In some embodiments, the fabrication process of FIGS. 2A-2F may be utilized for manufacturing of RF devices and/or modules described herein in reference to, for example, FIGS. 1A and 1B.

Referring to FIG. 2A, a fabrication state 210 may include a substrate 30 having a plurality of to-be-singulated units. For example, singulation can occur at boundaries depicted by dashed lines 205 so as to yield singulated individual units. As discussed above, the substrate 30 may be a packaging substrate (e.g., a laminate substrate), a semiconductor substrate, etc. The substrate 30 illustrated in FIGS. 2A-2F may be inverted (e.g., upside down) such that the first side of the substrate 30 (e.g., the upper side) faces downward and the second side of the substrate 30 (e.g., the underside) faces upward. In some embodiments, other components, modules, circuits, and/or devices may be located on the upper side of the substrate 30 (which is facing downward in FIG. 2A). For example, dies, circuits (e.g., RF circuits), etc., may be located on the upper side of the substrate 30 (not illustrated in the figures), as discussed above.

Referring to FIG. 2B, a fabrication state 220 may include a component 50 being mounted (e.g., attached, installed, fixed, etc.) to the underside of the substrate 30 (which is facing upward). One having ordinary skill in the art understands that the component 50 may be mounted onto the underside of the substrate 30 using various methods and/or processes.

Referring to FIG. 2C, a fabrication state 230 may include forming, implementing, depositing, placing, etc., support structures 20 (e.g., sets and/or groups of support structures 20) on the underside of the substrate 30 (which is facing upward). As discussed above, the support structures may be pillars, columns, posts, pedestals, spheres, balls, etc. One having ordinary skill in the art understands that the various methods, processes, technologies, etc., may be used to form the support structures 20. For example, a copper pillar bump/bumping process may be used to form the support structures 20 (which may be copper pillars/posts). In another example, a solder bump/bumping process may be used to form the set of support structures 20 (which may be solder balls). As illustrated in FIG. 2C, the support structures 20 define a mounting volume 40. The component 50 is positioned such that the component 50 is located within the mounting volume 40, as illustrated in FIGS. 1A and 1B. One having ordinary skill in the art understands that the fabrication states 230 and 220 may be reversed. For example, the support structures 20 may be formed (e.g., implemented, deposited, placed, etc.) on the substrate 30 first, and the component 50 may be mounted to the underside of the substrate after the support structures 20 are formed.

Referring to FIG. 2D, a fabrication state 240 may include individual units being singulated (at boundaries depicted by dashed lines 205) to yield a plurality of separate RF devices 10. One having ordinary skill in the art understands that such a singulation process can be achieved while the substrate 30 is in its inverted orientation (with the support structures facing upward as shown in the example of FIG. 2C), or while the substrate 30 is in its upright orientation (with the support structures 20 facing downward). One having ordinary skill in the art also understands that various methods, processes, and/or technologies may be used to singulate the individual units to yield the plurality of separate RF devices 10.

Referring to FIG. 2E, a fabrication state 250 may include flipping (e.g., inverting) the RF device 10 (or multiple RF devices 10) such that the first side of the substrate 30 (e.g., the upper side) faces upward and the second side of the substrate 30 (e.g., the underside where the support structures 20 are located) faces downward. The fabrication state 250 may also include mounting (e.g., installing, attaching, placing, affixing, etc.) the RF device 10 on a substrate 70. The substrate 70 may be a packaging substrate, such as a laminate substrate. As illustrated in close-up view (of the substrate 30, the support structure 20, and the substrate 70) in FIG. 2E, the RF device 10 may be mounted to the substrate 70 using solder material 80 (e.g., a solder paste, solder balls, etc.). The solder material 80 may allow the RF device 10 (e.g., the support structures 20 of the RF device 10) to be physically coupled (e.g., mounted, installed, attached, affixed, etc.) to the substrate 70. The solder material 80 may also provide thermal and/or electrical connections/conductivity between the RF device 10 and devices, components, modules, wires, pins, traces, etc., of the substrate 70. In one embodiment, the solder material 80 may be deposited onto the substrate 70 prior to mounting the RF device 10 on the substrate 70. For example, the solder material 80 may be deposited onto locations on the surface of the substrate 70 that may correspond to locations of the support structures 20 when the RF device 10 is mounted on the substrate 70. In another embodiment, the solder material 80 may be deposited on top of the support structures 20 prior to mounting the RF device 10 on the substrate 70. For example, referring to FIG. 2D, the solder material 80 may be deposited on top of the support structures 20 during the fabrication state 240, prior to inverting the RF device 10. In another example, referring to FIG. 2C, the solder material 80 may be deposited on top of the support structures 20 during the fabrication state 230, prior to singulating the individual units.

Referring to FIG. 2F, a fabrication state 240 may include implementing and/or forming overmold structure 60 between the substrate 30 and the substrate 70. In one embodiment, the overmold structure 60 may substantially encapsulate the support structures 20 in the fabrication state 240. For example, the vertical sides of one or more of the support structures 20 may be encapsulated by the overmold structure 60, as illustrated by the dotted lines outlining the support structures 20.

In one embodiment, the support structures 20 may help prevent the overmold material (e.g., a thermoplastic) of the overmold structure 60 from filling the mounting volume 40 during fabrication and/or manufacturing. For example, during a fabrication/manufacturing, the overmold material may be in a liquid form. As the overmold material is deposited over the support structures 20, the overmold material may flow between the substrate 30 and the substrate 70. The support structures 20 may block and/or may inhibit the flow of the overmold material to prevent the overmold material from filling the mounting volume 40 during fabrication and/or manufacturing.

In some embodiments, the layout of the support structures 20 (on the substrate 30) may help prevent the overmold material of the overmold structure 60 from filling the mounting volume 40 during fabrication and/or manufacturing. For example, the number of support structures 20, the spacing between the support structures 20, and/or the locations where the support structures 20 are formed (e.g., a pattern or positions of the support structures 20) may help prevent the overmold material of the overmold structure 60 from filling the mounting volume 40 during fabrication and/or manufacturing. In some embodiments, a lid or flat structure (e.g., made of a metallic, or plastic, epoxy or electrically insulative material) may be placed during a fabrication step over the one or more support structures to enhance the protection of the mounting volume 40 from exposure to overmold material.

In one embodiment, the layout of the support structures 20 may be based on the temperature of the overmold material of the overmold structure 60 during fabrication and/or manufacturing. For example, if the overmold material is at a higher temperature during fabrication and/or manufacturing, the overmold material may be less viscous (when compared to a lower temperature). The layout of the support structures 20 may have more support structures 20 and/or less spacing between the support structures 20 to prevent the overmold material from filling the mounting volume 40. In another example, if the overmold material is at a lower temperature during fabrication and/or manufacturing, the overmold material may be more viscous (when compared to a higher temperature). The layout of the support structures 20 may have fewer support structures 20 and/or more spacing between the support structures 20 to prevent the overmold material from filling the mounting volume 40.

In another embodiment, the layout of the set of support structures may be based on the amount of the overmold material of the overmold structure 60 during fabrication and/or manufacturing. For example, if more overmold material is used during fabrication and/or manufacturing, the layout of the support structures 20 may have more support structures 20 and/or less spacing between the support structures 20 to prevent the overmold material from filling the mounting volume 40. In another example, if less overmold material is used during fabrication and/or manufacturing, the layout of the support structures 20 may have fewer support structures 20 and/or more spacing between the support structures 20 to prevent the overmold material from filling the mounting volume 40.

In a further embodiment, the layout of the set of support structures may be based on a viscosity of the overmold material of the overmold structure 60 during fabrication and/or manufacturing. For example, if the overmold material is more viscous during fabrication and/or manufacturing, the layout of the support structures 20 may have fewer support structures 20 and/or more spacing between the support structures 20 to prevent the overmold material from filling the mounting volume 40. In another example, if less overmold material is less viscous during fabrication and/or manufacturing, the layout of the support structures 20 may have more support structures 20 and/or less spacing between the support structures 20 to prevent the overmold material from filling the mounting volume 40.

In one embodiment, the fabrication state 250 may include removing at least a portion of the overmold structure 60. For example, as the overmold material flows between the substrate 30 and the substrate 70, additional overmold material may be remain on the substrate 70 below the edges of the RF device 10 (e.g., below the edges of the substrate 30). The portion of the overmold structures 60 may be removed such that the vertical sides/surfaces of the substrate 30 are substantially flush/even with the vertical sizes/surfaces of the overmold structure 60. The portion of the overmold structure 60 may be removed using various different types of processes and/or methods. For example, the overmold structure 60 may be grinded (with an abrasive surface) to remove the portion of the overmold structure 60 (to expose a portion of the support structures 20). In another example, the portion of the overmold structure 60 may be removed using a laser to melt and/or burn the portion of the overmold structure 60 (to expose a portion of the support structures 20). In a further example, the portion of the overmold structure 60 may be ablated. For example, a stream of particles (e.g., water particles, sand particles, etc.) may be used to erode the portion of the overmold structure 60. In one embodiment, removing the portion of the overmold structure 60 may also remove a portion of the support structures 20. For example, ablating the overmold structure 60 may remove the top portions of the support structures 20 (which may shorten the height of the support structures 20).

In one embodiment, an RF module 90 may be result of the fabrication state 260. For example, after depositing the overmold structure 60 (and optionally removing portions of the overmold structure 60), the RF module 90 may be created/formed. The RF module 90 may include the substrate 70, the RF device 10, the support structures 20, the mounting volume 40, the component 50, and the overmold material 60. In other embodiment, the RF module 90 may also include other devices, components, modules, circuits, etc., that may be located on top of and/or within the substrate 70. For example, the RF module 90 may include another RF device, circuit, component, etc., that may also be mounted/installed on top of the substrate 70.

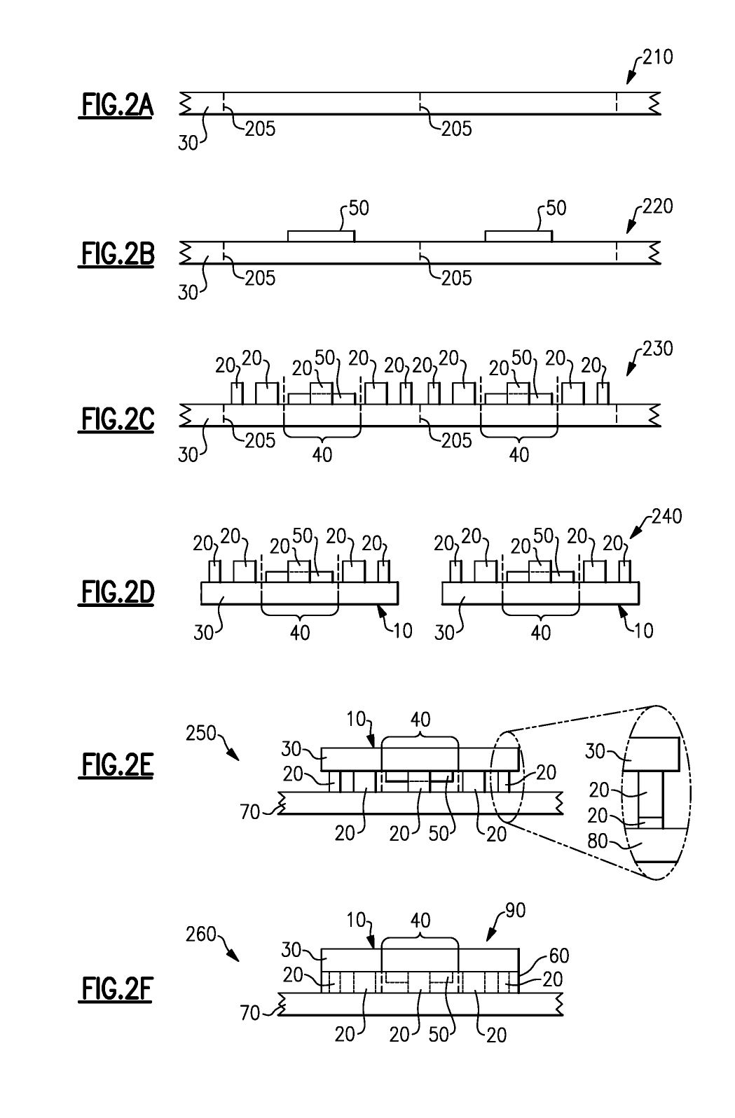

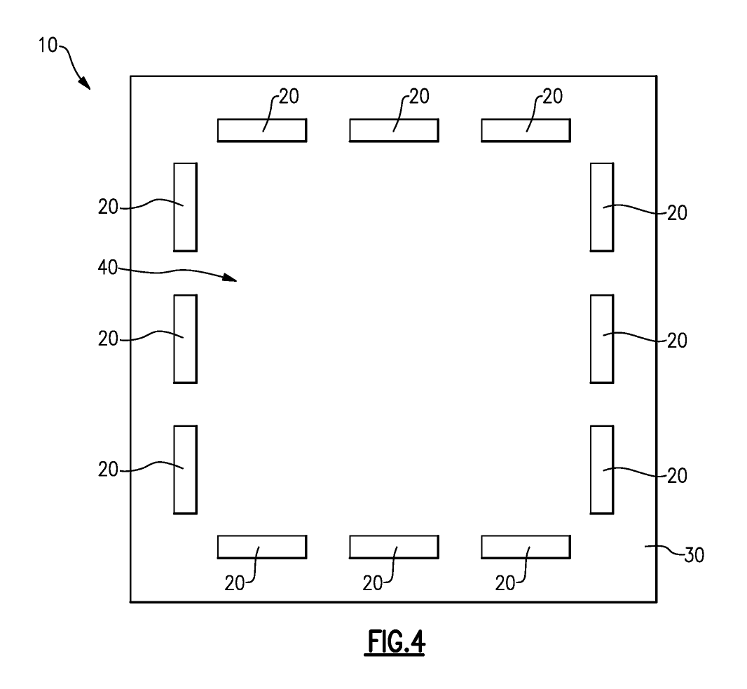

FIG. 3 illustrates an overhead (e.g., top-down) view of the bottom (e.g., underside) of an example RF device 10 during a manufacture/fabrication process, according to some embodiments of the present disclosure. As illustrated in FIG. 5, the RF device 10 includes a substrate 30 (e.g., a packaging substrate, a semiconductor substrate, etc.) and a component 50 mounted (e.g., installed, formed, implemented, etc.) on the substrate 30. In one embodiment, the view of the RF device 10 illustrated in FIG. 5 may be during the fabrication state 220 illustrated in FIG. 2B.

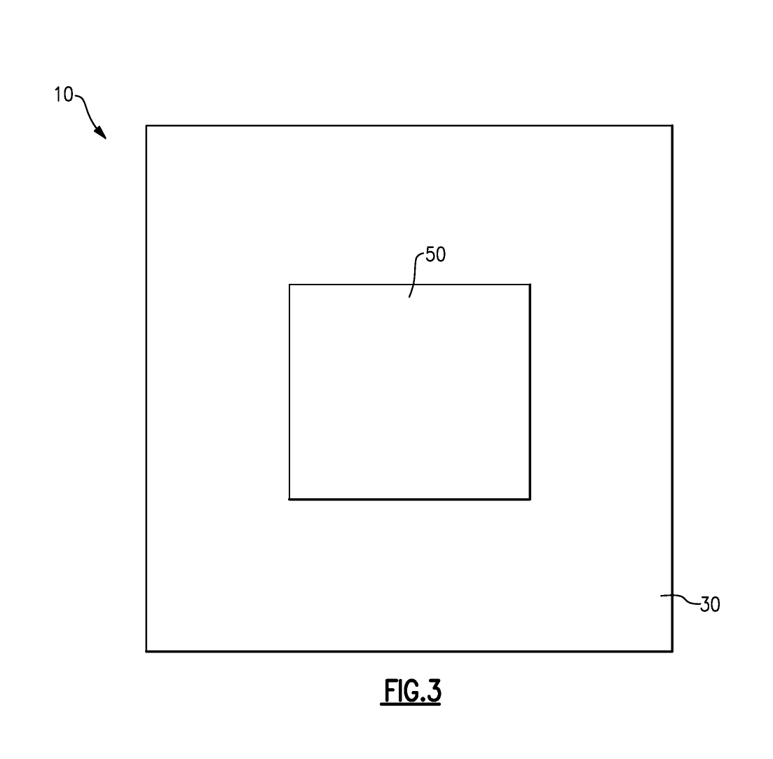

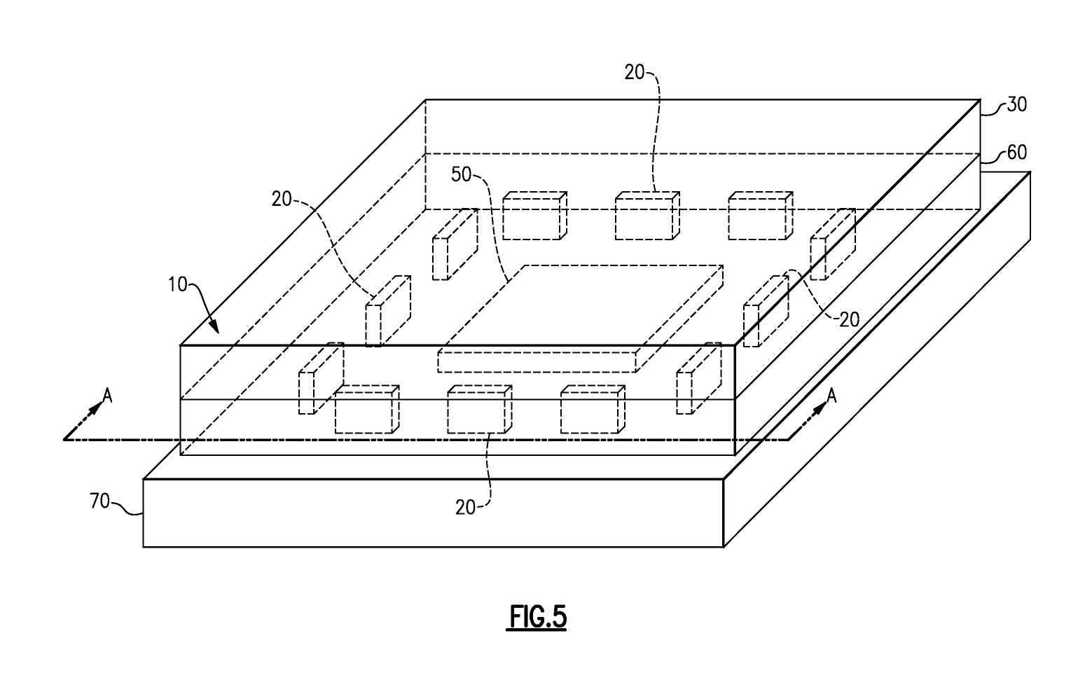

FIG. 4 illustrates an overhead (e.g., top-down) view of the bottom (e.g., underside) of an example RF device 10 during a manufacture/fabrication process, according to some embodiments of the present disclosure. As illustrated in FIG. 4, the RF device 10 includes a substrate 30 (e.g., a packaging substrate, a semiconductor substrate, etc.) and support structures 20 implemented (e.g., formed, created, etc.) on the substrate 30. The support structures 20 define a mounting volume 40. In one embodiment, the view of the RF device 10 illustrated in FIG. 6 may be during a fabrication state where the support structures are implemented (e.g., formed, deposited, etc.) on the substrate 30 prior to mounting a component (e.g., component 50 illustrated in FIG. 1A) in the mounting volume 40.

FIG. 5 illustrates as top-down perspective view of an RF module 90, according to some embodiments of the present disclosure. As discussed above, in one embodiment, the RF module 90 may include an RF device 10 mounted onto a substrate 70 (e.g., mounted using solder material). Also, as discussed above, the RF device may include a substrate 30, support structures 20 mounted on the surface of the substrate 30, and an overmold structure 60 (e.g., overmold material) between the substrate 30 (e.g., a semiconductor substrate such as a semiconductor die) and the substrate 70 (e.g., a packaging substrate such as a laminate substrate). As illustrated in FIG. 5, the support structures 20 may be substantially encapsulated by the overmold structure 60. Also as illustrated in FIG. 5, the component 50 is located within a mounting volume formed by the support structures 20 and the mounting volume may be substantially devoid of the overmold structure 60 (e.g., the overmold material). As discussed above, the mounting volume may be substantially devoid of the overmold structure 60. This may allow the component 50 to be mounted within the mounting volume. As illustrated in FIG. 1A, the component 50 may not be encapsulated by the overmold structure 60. FIG. 5 also includes a line A-A which may indicate a plane going through the overmold material 60.

FIG. 6 illustrates a top-down view of the RF device 10 (which may be mounted on a packaging substrate as part of an RF module) along the plane (parallel to the upper surface of the RF device 10) indicated by the line A-A of FIG. 5. As discussed above, the RF device 10 may be mounted onto a substrate (e.g., substrate 30 illustrated in FIG. 5). As illustrated in FIG. 6, support structures 20 form a mounting volume 40. The mounting volume 40 is substantially devoid of the overmold structure 60 (illustrated as the shaded area). For example, the mounting volume 40 may be substantially devoid (e.g., substantially free) of the overmold material (e.g., a thermoplastic) used in the overmold structure 60. In a further embodiment, a support structure may be any structure and/or component that may be used to prevent overmold material and/or the overmold structure 60 from filling the mounting volume 40 during a fabrication/manufacturing process, as discussed in more detail below. The overmold structure 60 may also be referred to as an overmold.

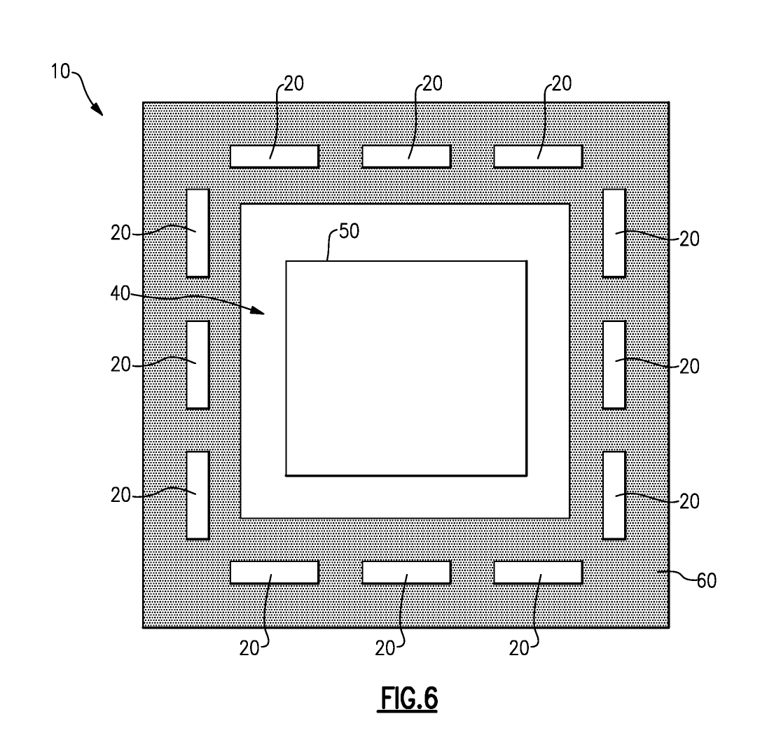

FIG. 7 illustrates an overhead (e.g., top-down) view of a bottom (e.g., an underside) of the example RF device 10, according to some embodiments of the present disclosure. As illustrated in FIG. 7, the RF device 10 includes a substrate 30 (e.g., a packaging substrate, a semiconductor substrate, etc.), a component 50 mounted (e.g., installed, formed, implemented, etc.) on the substrate 30, and support structures 20 implemented (e.g., formed, created, etc.) on the substrate 30. The support structures 20 define a mounting volume 40 and the component 50 is located in the mounting volume 40.

In one embodiment, the support structures 20 (e.g., the set of support structures) may be divided into two groups of support structures 20. A first group support structures 20 may be arranged to partially or fully surround the component 50 mounted on the second side of the substrate. For example, the first group of support structures may form a square/rectangular shaped perimeter (e.g., the inner square/rectangular shaped perimeter) around the mounting volume 40 and/or the component 50. The second group of support structures 20 may be arranged to partially or fully surround the first group of support structures 20. For example, the second group of support structures 20 may form a square/rectangular shaped perimeter around the first group of support structures 20, the mounting volume, and/or the component 50.

### Examples of Products Related to Dual-Sided Packages

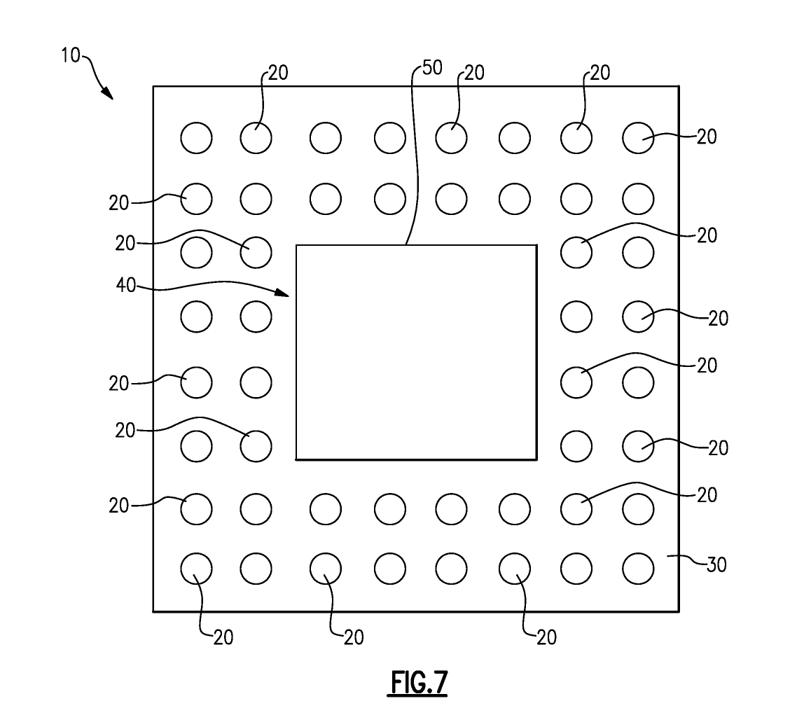

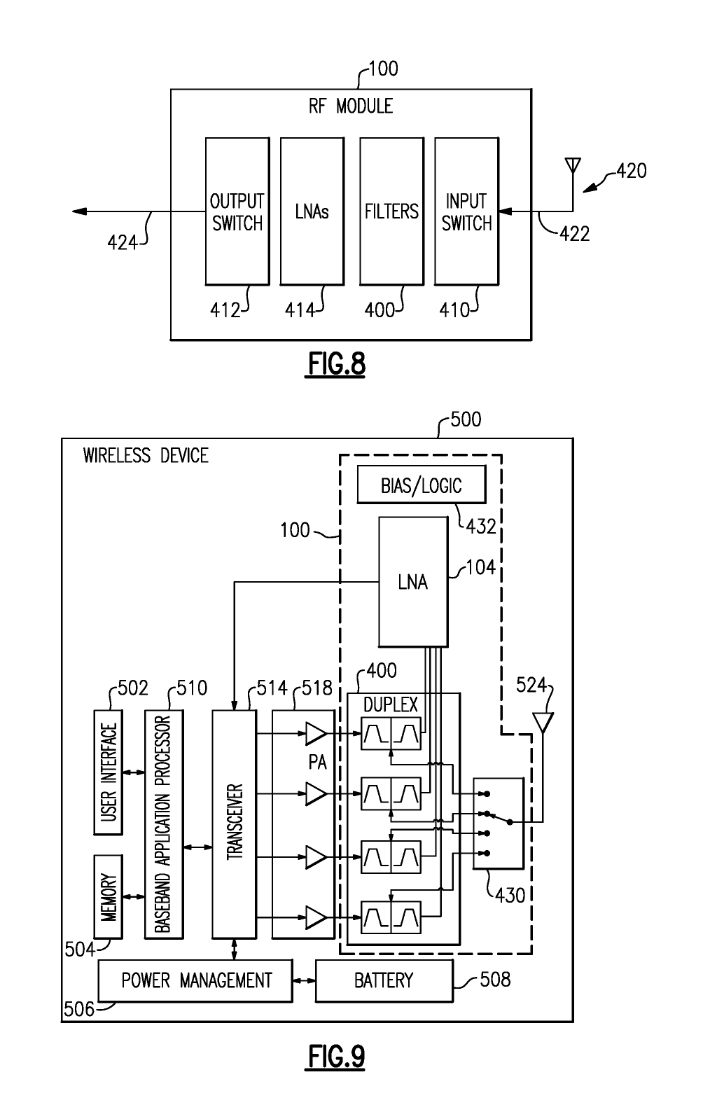

FIGS. 8 and 9 show examples of how the RF devices and/or RF modules described herein may be implemented in wireless devices. FIG. 8 shows that in some embodiments, a RF device having one or more features as described herein can be implemented as a RF module 100. Such a RF module 100 may be a used to transmit and/or receive RF signals. For example, the RF module 100 may be a diversity RX module that may be implemented relatively close to a diversity antenna 420 so as to minimize or reduce losses and/or noise in a signal path 422.

The diversity RX module can be configured such that switches 410 and 412, as well as LNAs 414, are implemented in a semiconductor die (depicted as 104) that is mounted underneath a packaging substrate. Filters 400 can be mounted on such a packaging substrate as described herein. In one embodiment, the filters 400 may include the RF devices described herein (e.g., RF device 10 illustrated and discussed above).

As further shown in FIG. 8, RX signals processed by the diversity RX module can be routed to a transceiver through a signal path 424. In wireless applications where the signal path 424 is relatively long and lossy, the foregoing implementation of the diversity RX module close to the antenna 420 can provide a number of desirable features.

FIG. 9 shows that in some embodiments, the RF devices and/or RF modules described herein may be implemented in wireless devices. For example, in an example wireless device 500 of FIG. 10, a RF module 100 (such as an LNA or LNA-related module) 100 may include the RF devices and/or modules described herein (e.g., RF device 10 illustrated and discussed above). Such a module may be utilized with a main antenna 524.

The example RF module 100 of FIG. 9 may include, for example, one or more LNAs 104, a bias/logic circuit 432, and a band-selection switch 430. Some or all of such circuits can be implemented in a semiconductor die that is mounted under a packaging substrate of the RF module 100. In such an RF module, some or all of duplexers 400 can be mounted on the packaging substrate so as to form a dual-sided package having one or more features as described herein.

FIG. 9 further depicts various features associated with the example wireless device 500. Although not specifically shown in FIG. 9, a diversity RX module can be included in the wireless device 500 with the RF module 100, in place of the RF module 100, or any combination thereof. It will also be understood that a RF module having one or more features as described herein can be implemented in the wireless device 500.

In the example wireless device 500, a power amplifier (PA) circuit 518 having a plurality of PAs can provide an amplified RF signal to a switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband sub-system 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device may include additional antennas such as diversity antenna, and additional connectivity features such as Wi-Fi, Bluetooth, and GPS.

### General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A radio-frequency module comprising:
a first substrate;
an RF device mounted on the first substrate, the RF device including a second substrate, the second substrate including a first side and a second side, a set of support structures implemented on the second side of the substrate, the set of support structures defining a mounting volume on the second side of the second substrate, and a component implemented within the mounting volume; and
a first overmold structure encapsulating at least a portion of the set of support structures.

2. The radio-frequency module of claim 1 wherein the radio-frequency device comprises a radio-frequency filter.

3. (canceled)

4. The radio-frequency module of claim 3 wherein the component comprises a resonator.

5. The radio-frequency module of claim 1 wherein the component is not encapsulated by the first overmold structure.

6. The radio-frequency module of claim 1 wherein the mounting volume is substantially devoid of the first overmold structure.

7. The radio-frequency module of claim 1 wherein the set of support structures is configured to prevent the first overmold structure from filling the mounting volume during a manufacturing process.

8. The radio-frequency module of claim 7 wherein a layout of the set of support structures prevents the first overmold structure from filling the mounting volume during a manufacturing process.

9. The radio-frequency module of claim 8 wherein the layout of the set of support structures is based on a temperature of the first overmold structure during the manufacturing process.

10. The radio-frequency module of claim 8 wherein the layout of the set of support structures is based on an amount of overmold material in the first overmold structure during the manufacturing process.

11. The radio-frequency module of claim 8 wherein the layout of the set of support structures is based on a viscosity of the first overmold structure during the manufacturing process.

12. The radio-frequency module of claim 1 wherein at least a portion of the set of support structures is exposed through the first overmold structure.

13. (canceled)

14. The radio-frequency module of claim 1 wherein the set of support structures is configured to allow the radio-frequency device to be mounted on the first substrate.

15. The radio-frequency module of claim 1 wherein the set of support structures comprises a first group of support structures arranged to partially or fully surround the component mounted on the second side of the second substrate.

16. The radio-frequency module of claim 15, wherein the set of support structures further comprises a second group of support structures arranged to partially or fully surround the first group of support structures.

17. The radio-frequency module of claim 1 wherein at least one support structure of the set of support structures is electrically connected to a circuit located on the second substrate.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. A method for manufacturing a radio-frequency module, the method comprising:
providing a first substrate configured to receive a plurality of components, the first substrate including a first side and a second side;
forming a set of support structures on the second side of the first substrate such that the set of support structures is positioned relative to the component, the set of support structures defining a mounting volume on the second side of the first substrate;
mounting a component within the mounting volume on the second side of the first substrate;
mounting the first substrate and the set of support structures on a second substrate; and
forming a first overmold structure between the first substrate and the second substrate, the mounting volume being substantially devoid of the first overmold structure.

32. The method of claim 31 further comprising:
mounting a circuit on the first side of the first substrate.

33. The method of claim 32 further comprising:
electrically connecting at least one support structure in the set of support structures to the circuit on the first side of the first substrate.

34. The method of claim 31 further comprising:
electrically connecting at least one support structure in the set of support structures to a ground plane in the second substrate.

35. (canceled)

36. (canceled)

37. A wireless device comprising:
a circuit board configured to receive a plurality of packaged modules; and
a radio-frequency module mounted on the circuit board, the radio-frequency device including a first substrate, an RF device mounted on the first substrate, the RF device including a second substrate, the second substrate including a first side and a second side, a set of support structures implemented on the second side of the substrate, the set of support structures defining a mounting volume on the second side of the second substrate, and a component implemented within the mounting volume, and a first overmold structure encapsulating at least a portion of the set of support structures.
